(19) United States
(12) Patent Application Publication
(10) Pub. No.: US 2026/0114097 A1
(43) Pub. Date: Apr. 23, 2026

(54) LIGHT EMITTING DISPLAY DEVICE AND METHOD OF MANUFACTURING THE SAME

(71) Applicant: Samsung Display Co., Ltd., Yongin-Si (KR)

(72) Inventors: Jong Min LEE, Yongin-si (KR); Dae Soo KIM, Yongin-si (KR); Min Yeul RYU, Yongin-si (KR); JUN HEO, Yongin-si (KR)

(21) Appl. No.: 19/270,511

(22) Filed: Jul. 16, 2025

(30) Foreign Application Priority Data
Oct. 23, 2024 (KR) 10-2024-0145720

(51) Int. Cl. H10H 29/39; H10H 29/01; H10H 29/37; H10H 29/41; H10K 59/12; H10K 59/122; H10K 59/123; H10K 59/124

(52) U.S. Cl. CPC H10H 29/39; H10H 29/012; H10H 29/37; H10H 29/41; H10K 59/1201; H10K 59/122; H10K 59/123; H10K 59/124

(57) ABSTRACT

A light emitting display device is disclosed that includes a substrate, a transistor, an insulating layer, a pixel electrode, a pixel defining layer, a spacer, and a protective layer. The transistor is positioned on the substrate and the insulating layer is positioned on the transistor. The pixel electrode is positioned on the insulating layer and electrically connected to the transistor. The pixel defining layer is positioned on the insulating layer and has an opening overlapping the pixel electrode. The spacer is positioned on the pixel defining layer and the protective layer is positioned on the spacer. The protective layer includes a first layer positioned on the spacer and a second layer positioned on the first layer.

### CROSS-REFERENCE TO RELATED APPLICATION

This application claims priority to and the benefit of Korean Patent Application No. 10-2024-0145720 filed at the Korean Intellectual Property Office on Oct. 23, 2024, the entire contents of which are incorporated herein by reference.

### BACKGROUND

### 1. Field

The present disclosure relates to a light emitting display device and a method of manufacturing the same, and more particularly, to a light emitting display device including a light emitting device and a method of manufacturing the same.

### 2. Description of the Related Art

A light emitting display device may include light emitting devices corresponding to pixels. An image may be displayed by controlling the brightness of each of the light emitting devices included in the light emitting display device. Unlike light receiving display devices such as liquid crystal displays, light emitting display devices do not require a light source such as a backlight, so their thickness and weight may be reduced. In addition, since the light emitting display device has the characteristics of high luminance, contrast ratio, color reproduction, and response speed, the image quality may be improved.

To provide high-quality images, light emitting display devices are being applied to various electronic devices such as mobile devices such as smartphones, tablets, laptop computers, monitors, and televisions, and are also being applied to automobile display devices.

### SUMMARY

A mask may be used when forming a light emitting layer in a light emitting display device. The mask may be supported by a spacer. The spacer that supports the mask may be pressed or stamped by the mask, resulting in defects such as dark spots.

Embodiments attempt to provide a display device capable of reducing defects such as dark spots by preventing the spacer from being pressed or stamped, and a method of manufacturing the same.

A light emitting display device according to an embodiment includes a substrate, a transistor positioned on the substrate, an insulating layer positioned on the transistor, a pixel electrode positioned on the insulating layer and electrically connected to the transistor, a pixel defining layer positioned on the insulating layer and having an opening overlapping the pixel electrode, a spacer positioned on the pixel defining layer, and a protective layer positioned on the spacer. The protective layer includes a first layer positioned on the spacer and a second layer positioned on the first layer.

The spacer may include a central portion including a center of the spacer, a step portion surrounding the central portion, and a peripheral portion surrounding the step portion, and the step portion may have a concave step in a direction of the pixel defining layer.

The protective layer may include a body positioned on the central portion and a protective layer wing positioned on the step portion.

The body may contact the central portion, and the protective layer wing may be spaced apart from the step portion.

A thickness of the wing may be smaller than a thickness of the body.

The end of the wing may have an internal angle of 30° to 50°.

The protective layer may not be positioned on the peripheral portion.

The protective layer may include a metal oxide.

The light emitting display device may include an intermediate layer positioned on at least one of the pixel electrode, the pixel defining layer, the spacer and the protective layer, and including a light emitting layer and a functional layer, and a common electrode positioned on the intermediate layer, wherein the protective layer may be positioned between the spacer and the intermediate layer.

The light emitting display device may include an encapsulation substrate positioned on the common electrode, a filler positioned between at least one of the substrate and the common electrode and the encapsulation substrate, and a sealing member positioned at an edge of the substrate and bonding the substrate and the encapsulation substrate.

An electronic device according to an embodiment includes a light emitting display device. The light emitting display device includes a substrate, a transistor positioned on the substrate, an insulating layer positioned on the transistor, a pixel electrode positioned on the insulating layer and electrically connected to the transistor, a pixel defining layer positioned on the insulating layer and having an opening overlapping the pixel electrode, a spacer positioned on the pixel defining layer, and a protective layer positioned on the spacer. The protective layer includes a first layer positioned on the spacer and a second layer positioned on the first layer.

A method of manufacturing a light emitting display device according to an embodiment includes forming a transistor on a substrate, forming an insulating layer on the transistor, forming a pixel electrode electrically connected to the transistor on the insulating layer, forming a pixel defining layer having an opening overlapping the pixel electrode on the insulating layer, forming a spacer on the pixel defining layer, and forming a protective layer on the spacer.

The forming of the protective layer includes forming a first layer on the spacer and forming a second layer on the first layer.

The forming of the protective layer may include forming a preliminary first layer on the spacer, etching the preliminary first layer to form an etched preliminary first layer, forming a preliminary second layer on the etched preliminary first layer and the spacer, and etching together the etched preliminary first layer and the preliminary second layer to form a first layer and a second layer.

The forming of the preliminary first layer may include depositing a first metal oxide on the spacer, and the forming of the preliminary second layer may include depositing a second metal oxide on the etched preliminary first layer and the spacer.

The method of manufacturing the light emitting display device may further include forming a step portion by ashing a portion of the spacer.

The forming of the step portion may include plasma-treating the surface of the step portion.

The forming of the step portion may be performed by ashing a region where the spacer does not overlap the etched preliminary first layer.

The spacer may include a central portion including a center of the spacer, a step portion surrounding the central portion, and a peripheral portion surrounding the step portion, and the forming of the first layer and the second layer may include etching the etched preliminary first layer and the preliminary second layer formed on the peripheral portion.

The etching of the preliminary first layer may include forming a first layer wing positioned on the step portion.

The forming of the second layer may include forming a second layer wing positioned on the first layer wing to form a protective layer wing.

The forming of the protective layer wing may include etching the preliminary first layer and the preliminary second layer so that the end of the protective layer wing has an inner angle of 30° to 50°.

According to embodiments, the spacer of the light emitting display device may be prevented from being pressed or stamped, thereby preventing the filler from penetrating into the common electrode, light emitting device, etc. Therefore, it is possible to suppress the occurrence of dark spots due to pressing and stamping of the spacer. Additionally, it is possible to suppress outgassing in the spacer and the pixel defining layer of the display device. Therefore, the occurrence of dots that can be seen from the outside may be prevented. Accordingly, the image quality of the display device may be improved, and defects in the display area of the display device may be reduced.

According to a method of manufacturing a display device according to an embodiment, the spacer of the display device may be prevented from being pressed or stamped, thereby preventing the filler from penetrating into the common electrode, light emitting device, etc. Additionally, it is possible to suppress outgassing in the spacer and the pixel defining layer. Therefore, defects such as dark spots and dot visibility may be prevented. Accordingly, a display device having improved image quality and reduced defects in the display area may be provided.

### BRIEF DESCRIPTION OF THE DRAWINGS

FIG. 1 is a schematic perspective view of an electronic device including a display device according to an embodiment.

FIG. 2 is a schematic perspective view of a display device according to an embodiment.

FIG. 3 is a cross-sectional view taken along the line I-I′ of FIG. 2 in the thickness direction.

FIG. 4 is a schematic cross-sectional view showing a portion of a display area of a display device according to an embodiment.

FIG. 5 is a schematic cross-sectional view of a spacer and a protective layer included in a display device according to an embodiment.

FIG. 6 is an enlarged view of region A of FIG. 5.

FIGS. 7, 8, 9, 10, and 11 are schematic cross-sectional views illustrating a method of manufacturing a protective layer according to an embodiment.

FIG. 12A is a photograph taken by an electron microscope of a portion of a spacer and a portion of a protective layer included in a display device according to an embodiment.

FIG. 12B is a line drawing of features shown in the photograph of FIG. 12A.

FIG. 13A is a photograph taken by an electron microscope of a portion of a spacer and a portion of a protective layer included in a display device according to an embodiment.

FIG. 13B is a line drawing of features shown in the photograph of FIG. 13A.

FIG. 14A is a photograph taken by an electron microscope of a portion of a spacer and a portion of a protective layer included in a display device according to a comparative example.

FIG. 14B is a line drawing of features shown in the photograph of FIG. 14A.

FIG. 15 is a block diagram of an electronic device according to some embodiments.

FIG. 16 is a schematic diagram of electronic devices according to some embodiments.

### DETAILED DESCRIPTION

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

Further, since sizes and thicknesses of components shown in the accompanying drawings may be arbitrarily given to facilitate understanding and ease of description, the disclosure is not limited to the illustrated sizes and thicknesses. In the drawings, the thicknesses of layers and regions are exaggerated for clarity. In the drawings, to facilitate understanding and ease of description, the thicknesses of some layers and regions may be exaggerated.

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, when an element is referred to as being “on” or “above” a reference element, it may be positioned above or below the reference element, and it may not necessarily be referred to as being positioned “on” or “above” it in a direction opposite to gravity.

In addition, unless explicitly described to the contrary, the words “comprise” and “includes,” and variations such as “comprises” and “comprising,” should be understood to imply the inclusion of stated elements but not the exclusion of any other elements.

In addition, the phrase “on a plane” means a view from a position above the object (e.g., from the top), and the phrase “in a cross-section” means a view of a cross-section of the object which is vertically cut from the side.

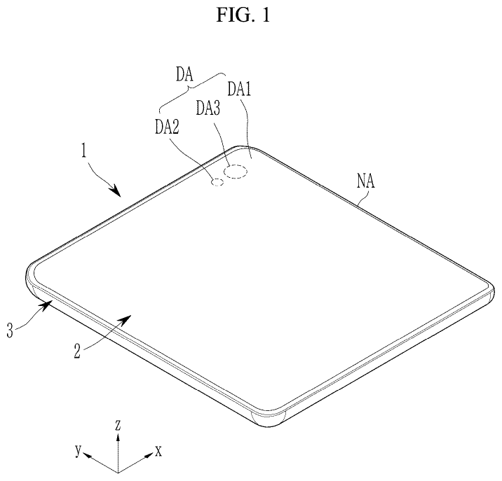

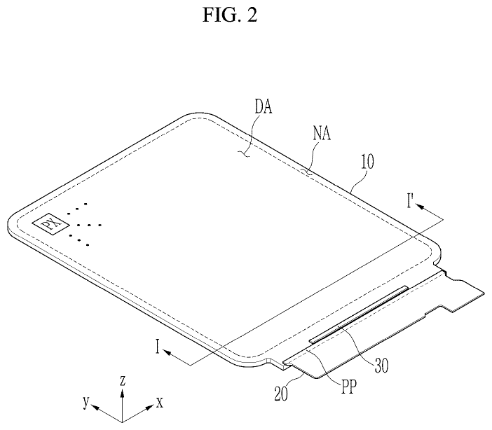

FIG. 1 is a schematic perspective view of an electronic device including a display device according to an embodiment. FIG. 2 is a schematic perspective view of a display device according to an embodiment.

Referring to FIGS. 1 and 2, an electronic device 1 may include a display screen capable of displaying an image in a third direction (z) corresponding to a front on a plane defined by a first direction (x) and a second direction (y). For example, the electronic device 1 may include a television, a mobile phone, a smartphone, a tablet, a notebook computer, a monitor, a multimedia player, a billboard, an electronic watch, a smartwatch, a watch phone, a head mounted display (HMD), a mobile communication terminal, an electronic notebook, an electronic book, a portable multimedia player (PMP), a navigation game machine, a digital camera, a camcorder, and the like.

The electronic device 1 may include a cover window 2, a housing 3, a display device, etc.

The cover window 2 may include an insulating pattern. For example, the cover window 2 may include glass, plastic or a combination thereof. The front of the cover window 2 may define the front of the electronic device 1. The region corresponding to the display screen in the cover window 2 may be optically transparent. The cover window 2 is positioned on the display device and may protect the display device from external impacts, etc., and may transmit an image displayed by the display device.

The housing 3 may be made of a material having relatively high rigidity. For example, the housing 3 may include a plurality of frames or plates made of glass, plastic, or metal, or a combination thereof. The housing 3 may be coupled with the cover window 2, and the coupled housing 3 and cover window 2 may form the exterior of the electronic device 1 and provide an internal space of the electronic device 1. For example, the housing 3 may form the back and side of the electronic device 1, and the cover window 2 may form the front of the electronic device 1. A display device, etc. may be positioned in the internal space defined by the cover window 2 and the housing 3, and the display device, etc. may be protected from the external environment.

The display device may display an image and provide a display screen of the electronic device 1. The display device may be a light emitting display device such as an organic light emitting display device, an inorganic light emitting display device, or a quantum-dot light emitting display device.

The electronic device 1 may have various shapes. For example, the electronic device 1 may be a quadrangle with rounded corners when viewed from the front as illustrated in FIG. 1. In addition, the electronic device 1 may have a shape such as a rectangle, square, other polygon, circle, or oval.

The electronic device 1 and the display device may include a display area DA and a non-display area NA, respectively. The display area DA and the non-display area NA illustrated in FIG. 1 may correspond to the display area DA and the non-display area NA of the display device illustrated in FIG. 2, respectively. The display area DA is the area where the image is displayed and may correspond to the display screen. The non-display area NA may be an area where the image is not displayed. The display area DA may occupy most of the area based on the center of the front of the electronic device 1, and the non-display area NA may surround the display area DA.

As shown in FIG. 1, the display area DA may include a first display area DA1, a second display area DA2, and a third display area DA3. The second display area DA2 and the third display area DA3 may be areas where components such as sensors and cameras are disposed at the back for adding various functions to the electronic device 1. The second display area DA2 and the third display area DA3 may correspond to a component area. The second display area DA2 and the third display area DA3 may be surrounded by the first display area DA1. Not only the first display area DA1, but also the second display area DA2 and the third display area DA3 may all display images. The positions and numbers of the second display area DA2 and the third display area DA3 may be varied.

To describe the display device in more detail, the display device may provide a display screen in the electronic device 1. The display device may detect or capture the front of the electronic device 1. The display device may have a flat form similar to an electronic device.

The display device may include a display panel 10, a flexible printed circuit board 20 bonded to the display panel 10, and a driving unit including an integrated circuit chip 30.

The display panel 10 may include the display area DA corresponding to a screen on which an image is displayed and the non-display area NA in which circuits and signal lines for generating and transmitting various signals applied to the display area DA are disposed. The non-display area NA may surround the display area DA. In FIG. 2, each of the inner side and outer side of the dotted rectangle may correspond to the display area DA and the non-display area NA, and may correspond to the display area DA and the non-display area NA of the electronic device 1 described with reference to FIG. 1. In FIG. 2, for convenience of description, the first display area DA1, the second display area DA2, and the third display area DA3 are not separated, but the display area DA may include the first display area DA1, the second display area DA2, and the third display area DA3 as in FIG. 1.

Pixels PX may be disposed in a matrix in the display area DA of the display panel 10. Additionally, signal lines such as gate lines, data lines, and driving voltage lines may be disposed in the display area DA. The gate line may extend in the first direction x, and the data line and driving voltage line may extend in the second direction y. Signal lines such as a gate line, a data line, and a driving voltage line are connected to each pixel PX, so that each pixel PX may receive a gate signal (also referred to a scan signal), a data voltage, and a driving voltage from the signal lines. Each pixel PX may include a light emitting device and a pixel circuit connected thereto. The pixel circuit may generate a driving current based on signals applied through signal lines such as gate lines and data lines, and may apply the driving current to the light emitting device.

A touch sensor may be disposed in the display area DA to detect a user's contact and non-contact touch. In FIG. 1, the display area DA is shown as a quadrangle, but the display area DA may have various shapes other than a quadrangle, such as a polygon, circle, or oval.

A pad portion PP in which pads for receiving signals from the outside of the display panel 10 are arranged may be positioned in the non-display area NA of the display panel 10. The pad portion PP may be positioned in the first direction (x) along any one edge of the display panel 10. The flexible printed circuit board 20 may be bonded to the pad portion PP, and pads of the flexible printed circuit board 20 may be electrically connected to pads of the pad portion PP.

A driving unit that generates and processes various signals for driving the display panel 10 may be positioned in the non-display area NA of the display panel 10. The driving unit may include a data driver that applies a data voltage to data lines, a gate driver that applies a gate signal to gate lines, and a signal controller that controls the data driver and the gate driver. The pixels PX may receive a data voltage according to a gate signal generated by the gate driver. The gate driver may be integrated into the display panel 10 and may be positioned on at least one side of the display area DA. The data driver and the signal controller may be provided as the integrated circuit chip (also referred to a driving IC chip or driving IC) 30, and the integrated circuit chip 30 may be mounted on the non-display area NA of the display panel 10. The integrated circuit chip 30 may be mounted on the flexible printed circuit board 20 or the like and electrically connected to the display panel 10.

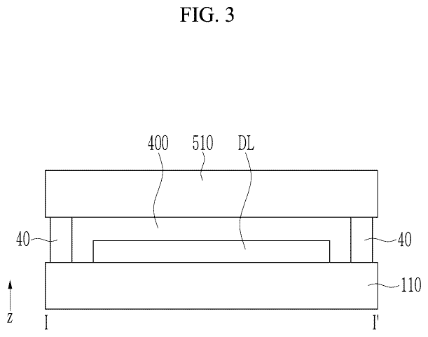

FIG. 3 is a schematic cross-sectional view taken along line I-I′ of FIG. 1.

Referring to FIG. 3, the light emitting display device may include a substrate 110, a display layer DL positioned on the substrate 110, and an encapsulation substrate 510 positioned on the display layer DL. A filler 400 may be positioned between at least one of the substrate 110 and the display layer DL and the encapsulation substrate 510, and a sealing member 40 may be positioned at the edge of the substrate 110 and the edge of the encapsulation substrate 510.

The substrate 110 may be a rigid substrate including a material such as glass. The substrate 110 may be a flexible substrate including a polymer resin such as polyimide, polyamide, or polyethylene terephthalate.

The encapsulation substrate 510 may be formed of substantially the same material as the substrate 110. For example, the encapsulation substrate 510 may be a rigid substrate including a material such as glass. For example, the encapsulation substrate 510 may be a flexible substrate including a polymer resin.

The filler 400 may be positioned between at least one of the substrate 110 and the display layer DL and the encapsulation substrate 510. One surface of the filler 400 may be in contact with at least one of the substrate 110 and a capping layer of the display layer DL, and the other surface of the filler 400 may be in contact with the encapsulation substrate 510.

The filler 400 may fill the space between at least one of the substrate 110 and the display layer DL and the encapsulation substrate 510 to increase the compression resistance between the substrate 110 and the encapsulation substrate 510, or between the display layer DL and the encapsulation substrate 510. The filler 400 may be formed by printing or applying a filler material on the encapsulation substrate 510, bonding the encapsulation substrate 510 to the substrate 110, and then curing it. The filler 400 may be formed by printing or applying a filler material on the substrate 110, bonding the substrate 110 to the encapsulation substrate 510, and then curing it. The filler 400 may include an organic material such as an epoxy resin, a polyacrylate resin, a phenolic resin, a polyester resin, etc.

The substrate 110 and the encapsulation substrate 510 may be bonded and sealed by the sealing member 40. The sealing member 40 may be formed at the edge of the substrate 110 and the edge of the encapsulation substrate 510 to bond the substrate 110 and the encapsulation substrate 510. For example, the sealing member 40 may be positioned in the non-display area described with reference to FIGS. 1 and 2.

The sealing member 40 formed at the edge of the encapsulation substrate 510 may be positioned at the edge of the substrate 110 on which the display layer DL is formed. After the substrate 110 and the encapsulation substrate 510 are overlapped, a laser is irradiated on the sealing member 40 to cure it, thereby bonding the substrate 110 and the encapsulation substrate 510.

The sealing member 40 may include a photocurable material. The sealing member 40 may include frit. The frit may refer to glass raw material in powder form, and may also refer to a paste state containing laser or infrared absorbers, organic binders, fillers, etc., in silicon dioxide (SiO₂). The sealing member 40 may include an epoxy acrylate-based resin, a polyester acrylate-based resin, a urethane acrylate-based resin, a polybutadiene acrylate-based resin, a silicone acrylate-based resin, an alkyl acrylate-based resin, and the like.

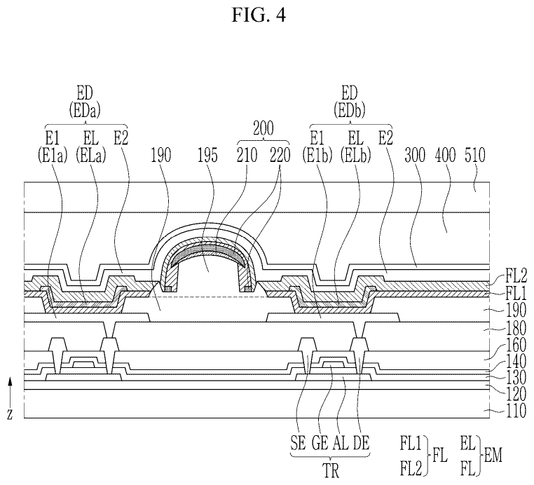

FIG. 4 is a schematic cross-sectional view showing a portion of a display area of a display device according to an embodiment. FIG. 4 shows a portion of the display device corresponding to approximately two pixel areas.

Referring to FIG. 4, a buffer layer 120 may be positioned on the substrate 110. The buffer layer 120 may block impurities from the substrate 110 when forming a semiconductor layer, thereby improving the characteristics of the semiconductor layer, and may alleviate stress on the semiconductor layer by planarizing the surface of the substrate 110. The buffer layer 120 may be an inorganic insulating layer that may include an inorganic insulating material such as silicon nitride (SiNₓ), silicon oxide (SiOₓ), or silicon oxynitride (SiOₓN_{y}), and may have a single-layer structure or a multi-layer structure.

A transistor TR may be positioned on the substrate 110. For example, the transistor TR may be positioned on the buffer layer 120 which is positioned on the substrate 110.

A semiconductor layer AL of the transistor TR may be positioned on the substrate 110. The semiconductor layer AL may include a first semiconductor region, a second semiconductor region, and a channel region positioned between the first semiconductor region and the second semiconductor region. The semiconductor layer AL may include any one of amorphous silicon, polycrystalline silicon, and oxide semiconductor. For example, the semiconductor layer AL may include low-temperature polycrystalline silicon (LTPS) or an oxide semiconductor material including at least one of zinc (Zn), indium (In), gallium (Ga), and tin (Sn). For example, the semiconductor layer AL may include indium gallium zinc oxide IGZO.

A first gate insulating layer 130 may be positioned on the semiconductor layer AL. The first gate insulating layer 130 may include an inorganic insulating material such as silicon nitride, silicon oxide, or silicon oxynitride. The first gate insulating layer 130 may have a single-layer structure or a multi-layer structure.

A gate conductive layer that may include a gate electrode GE of the transistor TR, etc., may be positioned on the first gate insulating layer 130. The gate conductive layer may include molybdenum (Mo), aluminum (Al), copper (Cu), titanium (Ti), etc., and may have a single-layer structure or a multi-layer structure.

A second gate insulating layer 140 may be positioned on the gate conductive layer. The second gate insulating layer 140 may include an inorganic insulating material such as silicon nitride, silicon oxide, or silicon oxynitride. The second gate insulating layer 140 may have a single-layer structure or a multi-layer structure.

An interlayer insulating layer 160 may be positioned on the second gate insulating layer 140. The interlayer insulating layer 160 may include an inorganic insulating material such as silicon nitride, silicon oxide, or silicon oxynitride. The interlayer insulating layer 160 may have a single-layer structure or a multi-layer structure. An additional gate conductive layer may be positioned on the interlayer insulating layer 160.

A data conductive layer that may include a first electrode SE and a second electrode DE of the transistor TR may be positioned on the interlayer insulating layer 160. The first electrode SE and the second electrode DE may be connected to the first semiconductor region and the second semiconductor region of the semiconductor layer AL, respectively, through contact holes formed in the insulating layers 130, 140, and 160. One of the first electrode SE and the second electrode DE may be a source electrode and the other may be a drain electrode.

The data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and the like, and may have a single-layer structure or a multi-layer structure. For example, the data conductive layer may include a lower layer including a refractory metal, such as molybdenum, chromium, tantalum, or titanium, an intermediate layer including a low-resistivity metal, such as aluminum, copper, or silver, and an upper layer including a refractory metal. For example, the data conductive layer may have a triple-layer structure such as titanium (Ti)/aluminum (Al)/titanium (Ti).

An insulating layer 180 may be positioned on the data conductive layer. The insulating layer 180 positioned on the data conductive layer may be provided as a planarized layer. For example, the insulating layer 180 provided as a planarized layer may be positioned on the transistor TR including the semiconductor layer AL, the gate electrode GE, the first electrode SE, and the second electrode DE. The insulating layer 180 may be positioned on the second gate insulating layer 140.

The insulating layer 180 may include an organic insulating material including a common general polymer, such as a poly(methyl methacrylate) or a polystyrene, a polymer derivative having a phenol-based group, an acryl-based polymer, an imide-based polymer (e.g., polyimide), or a siloxane-based polymer.

In an embodiment, a light emitting device ED may be positioned on the insulating layer 180. For example, the light emitting device ED is positioned on the insulating layer 180 provided as a planarized layer and may be electrically connected to the transistor TR.

The light emitting device ED may include a pixel electrode E1. For example, the pixel electrode E1 may be an anode of the light emitting device. The pixel electrode E1 may be electrically connected to the transistor TR. For example, the pixel electrode E1 may be connected to the second electrode DE of the transistor TR through a contact hole formed in the insulating layer 180. The pixel electrode E1 may be formed of a reflective conductive material or a semi-transparent conductive material, or may be formed of a transparent conductive material. The pixel electrode E1 may include a metal or metal alloy such as lithium (Li), calcium (Ca), aluminum (Al), silver (Ag), magnesium (Mg), or gold (Au). The pixel electrode E1 may be multilayered, and may have a triple-layer structure such as indium tin oxide (ITO)/silver (Ag)/ITO, for example.

A pixel defining layer 190 having an opening overlapping the pixel electrode E1 may be positioned on the insulating layer 180. The pixel electrode E1 may be positioned in an opening of the pixel defining layer 190. The opening may correspond to the light emitting region of the light emitting device.

The pixel defining layer 190 may include an organic insulating material including a common general polymer, such as a poly(methyl methacrylate) or a polystyrene, a polymer derivative having a phenol-based group, an acryl-based polymer, an imide-based polymer, or a siloxane-based polymer.

A spacer 195 may be positioned on the pixel defining layer 190. The spacer 195 is positioned on the pixel defining layer 190 and may support a mask for forming a light emitting layer, which will be described later. The spacer 195 may be formed of substantially the same material as the pixel defining layer 190. For example, the pixel defining layer 190 and the spacer 195 may be formed of the same material in the same process. The pixel defining layer 190 and the spacer 195 may be formed integrally by one process, but may also be formed separately by separate processes.

A protective layer 200 may be positioned on the spacer 195. The protective layer 200 may be positioned between the spacer 195 and an intermediate layer EM. In an embodiment, the protective layer 200 may include a first layer 210 positioned on the spacer 195 and a second layer 220 positioned on the first layer 210.

The intermediate layer EM may be positioned on at least one of the pixel electrode E1, the pixel defining layer 190, the spacer 195, and the protective layer 200. The intermediate layer EM may include a light emitting layer EL and a functional layer FL.

The light emitting layer EL is a layer in which electro-optic transfer occurs through a combination of electrons and holes, and may include at least one of an organic material and an inorganic material that emits light of a predetermined color. The light emitting layer EL may be positioned in the opening of the pixel defining layer 190 and may overlap the pixel electrode E1. A portion of the light emitting layer EL may be positioned on the pixel defining layer 190. The light emitting layer EL may include an organic light emitting diode or an inorganic light emitting diode.

The functional layer FL may include at least one of a hole injection layer, a hole transport layer, an electron transport layer, and an electron injection layer. The functional layer FL may include a first functional layer FL1 positioned between the pixel electrode E1 and the light emitting layer EL, and a second functional layer FL2 positioned between the light emitting layer EL and a common electrode E2. The first functional layer FL1 may include at least one of a hole injection layer and a hole transport layer. The second functional layer FL2 may include at least one of an electron transport layer and an electron injection layer. The functional layer FL may be positioned across the entire display area DA as described with reference to FIG. 1. The functional layer FL may be positioned in the opening of the pixel defining layer 190. The functional layer FL may be disposed outside the opening of the pixel defining layer 190.

The common electrode E2 may be disposed on the intermediate layer EM. The pixel electrode E1 may be an anode of the light emitting device ED, and the common electrode E2 may be a cathode of the light emitting device ED. The common electrode E2 may be positioned across the entire display area DA as described with reference to FIGS. 1 and 2.

The common electrode E2 may include a metal or metal alloy having a low work function, such as calcium (Ca), barium (Ba), magnesium (Mg), aluminum (Al), or silver (Ag). For example, light transparency may be achieved by forming a thin layer of a metal or metal alloy having the low work function. The common electrode E2 may include a transparent conductive oxide such as ITO or indium zinc oxide IZO.

The common electrode E2 may form the light emitting device ED together with the pixel electrode E1 and the intermediate layer EM. For example, the pixel electrode E1, the light emitting layer EL, and the common electrode E2 may form the light emitting device ED. The light emitting device ED may include the functional layer FL including the first functional layer FL1 and the second functional layer FL2.

The light emitting layer EL may include the light emitting layers ELa and ELb that display different colors. For example, the light emitting layer EL may include a first light emitting layer ELa that displays a first color and a second light emitting layer ELb that displays a second color different from the first color. For example, the first light emitting layer ELa and the second light emitting layer ELb may each display different colors among red, green, and blue. The first light emitting layer ELa and the second light emitting layer ELb may be spaced apart from each other with the pixel defining layer 190 therebetween.

The pixel electrode E1 may include a first pixel electrode Ela and a second pixel electrode E1b. The first light emitting layer ELa may be positioned on the first pixel electrode Ela. The second light emitting layer ELb may be positioned on the second pixel electrode E1b. The first pixel electrode Ela and the second pixel electrode E1b may be spaced apart from each other with the pixel defining layer 190 therebetween.

The first pixel electrode Ela, the first light emitting layer ELa, and the common electrode E2 may form a first light emitting device EDa. The second pixel electrode E1b, the second light emitting layer ELb, and the common electrode E2 may form a second light emitting device EDb. The first light emitting device EDa and the second light emitting device EDb may each include the functional layer FL including the first functional layer FL1 and the second functional layer FL2.

The light emitting device ED may correspond to the pixel PX described with reference to FIG. 1. The first light emitting device EDa and the second light emitting device EDb correspond to different pixels and may display different colors. For example, the first light emitting device EDa and the second light emitting device EDb may each correspond to different pixels and may each display one of the colors red, green, and blue.

A capping layer 300 may be positioned on the common electrode E2. The capping layer 300 may improve light efficiency by adjusting the refractive index.

The filler 400 may be positioned on the capping layer 300. The filler 400 may be positioned between the encapsulation substrate 510 and the light emitting device ED to protect the light emitting device ED from external or internal impact.

The encapsulation substrate 510 may be positioned on the filler 400. The encapsulation substrate 510 may encapsulate the display layer DL, particularly the light emitting device ED, to prevent moisture or oxygen from penetrating from the outside. Instead of or together with the encapsulation substrate 510, a thin-film encapsulation layer including one or more inorganic layers and one or more organic layers may be positioned on the capping layer 300.

A touch sensor layer (not shown) may be positioned on the encapsulation substrate 510, and an anti-reflection layer (not shown) may be positioned on the touch sensor layer to reduce external light reflection.

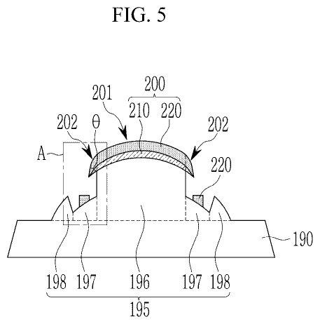

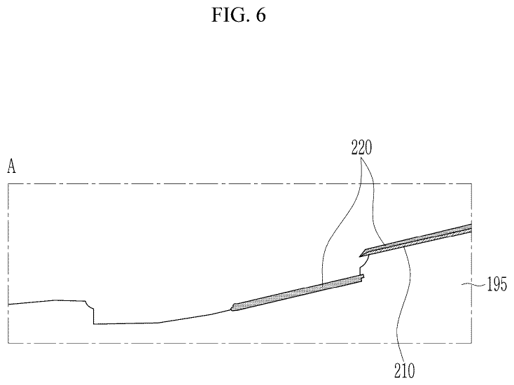

FIG. 5 is a schematic cross-sectional view of a spacer and a protective layer included in a display device according to an embodiment. FIG. 6 is an enlarged view of region A of FIG. 5.

In describing FIGS. 5 and 6, cross-reference may be made to FIG. 4.

Referring to FIGS. 5 and 6, the protective layer 200 positioned on the spacer 195 may include the first layer 210 and the second layer 220.

The spacer 195 may include a central portion 196 including the center of the spacer 195, a step portion 197 surrounding the central portion 196, and a peripheral portion 198 surrounding the step portion 197. The central portion 196 may refer to a region from the center of the spacer 195 to a predetermined distance. The step portion 197 may refer to a region from the outer edge of the central portion 196 to a predetermined distance. The step portion 197 may have a concave step from the upper surface of the central portion 196 and the peripheral portion 198 in the direction of the pixel defining layer 190. The peripheral portion 198 may refer to a region from the outer edge of the step portion 197 to the outer edge of the spacer 195. The height of the peripheral portion 198 may be less than the height of the central portion 196. The spacer 195 may include the central portion 196, the step portion 197, and the peripheral portion 198.

For example, the light emitting layer EL described with reference to FIG. 4 may be deposited using a mask such as a fine metal mask, and the mask may be in contact with the spacer 195. Pressure may be applied to the spacer 195 by the mask, which may cause cracks to occur in the spacer 195. Cracks formed in the spacer 195 may cause cracks to occur in the intermediate layer EM, the common electrode E2, and the capping layer 300 positioned on the spacer 195. Materials of the filler 400 positioned on the capping layer 300 may flow into the intermediate layer EM through the cracks. Therefore, dark spots may occur in regions where the filler is introduced. In addition, outgassing may occur in the spacer 195 due to cracks formed in the spacer 195, resulting in dot stains.

However, the protective layer 200 may be positioned on the spacer 195 to prevent cracking of the spacer 195 due to a mask or the like. Accordingly, it is possible to prevent the filler from flowing into the intermediate layer through the cracks, and suppress outgassing from occurring through the cracks formed in the spacer 195. Therefore, it is possible to prevent the occurrence of dark spots or dot stains in the display area.

The protective layer 200 may be positioned on the central portion 196 of the spacer 195. The protective layer 200 may completely cover the central portion 196 of the spacer 195, and both sides of the protective layer 200 may protrude laterally from the central portion 196. The protective layer 200 may include a body 201 positioned on the central portion 196 and a wing 202 positioned on the step portion 197. The body 201 may refer to a region of the protective layer 200 positioned on the central portion 196 of the spacer 195. The wing 202 may refer to a region of the protective layer 200 positioned on the step portion 197 of the spacer 195. The wing 202 may not overlap the central portion 196, but may overlap the step portion 197. The protective layer 200 may prevent dark spots from occurring due to defects that may occur at the step portion 197 due to pressure being applied to the spacer 195 by, for example, a mask for deposition of the light emitting layer EL, including the wing 202.

The body 201 may contact the central portion 196. The body 201 may include a body of the first layer 210 and a body of the second layer 220. For example, the body 201 may include a body of the first layer 210 in contact with the central portion 196 and a body of the second layer 220 in contact with the body of the first layer 210.

The wing 202 may be spaced apart from the step portion 197. The wing 202 may include a wing of the first layer 210 and a wing of the first layer 210. For example, the wing 202 may include a region of the first layer 210 positioned on the step portion 197 and spaced apart from the step portion 197 and a region of the second layer 220 positioned on the region of the first layer 210 spaced apart from the step portion 197. The penetration of foreign substances into the step portion 197 may be prevented by the wing 202 spaced apart from the step portion 197. Accordingly, dark spots caused by foreign substances penetrating the step portion 197 may be prevented.

In an embodiment, the thickness of the wing 202 may be less than the thickness of the body 201. The end of the wing 202 may have a chamfered shape. For example, the wing 202 may have an oblique inclined surface in the end direction of the wing 202. The inclined surface may be formed in the direction of the end of the wing 202 from the boundary of the body 201 and the wing 202. Accordingly, the thickness of the wing 202 may be less than the thickness of the body 201.

The end of the wing 202 may have an internal angle θ of about 30° to about 50°, about 35° to about 50°, or about 35° to about 45°. For example, the end of the wing 202 may have an inclined surface to have an inner angle within the above range. In the above inner angle range, the wing 202 may be prevented from becoming too thin. Accordingly, the wing 202 may be prevented from breaking, thereby preventing damage to the step portion 197 of the spacer 195.

In an embodiment, the protective layer 200 may not be formed on the peripheral portion 198 of the spacer 195. For example, the protective layer 200 may be formed on the central portion 196 and on a portion of the step portion 197 of the spacer 195. The first layer 210 and the second layer 220 of the protective layer 200 may be positioned together on the central portion 196. The first layer 210 and the second layer 220 of the protective layer 200 may be positioned together on the step portion 197. For example, the first layer 210 and the second layer 220 may be positioned on the step portion 197 as the wings 202 spaced apart from the step portion 197. For example, a portion of the second layer 220 may be positioned on the step portion 197 in contact with the step portion 197. The protective layer 200 may be formed only on the central portion 196 of the spacer 195.

The protective layer 200 may include a metal oxide. For example, the protective layer 200 may include IGZO, IZO, indium zinc tin oxide (IZTO), ITO, zinc tin oxide (ZTO), or the like. The protective layer 200 may include a metal oxide such as zinc (Zn), indium (In), gallium (Ga), tin (Sn), or titanium (Ti). The first layer 210 and the second layer 220 may include the metal oxide described above.

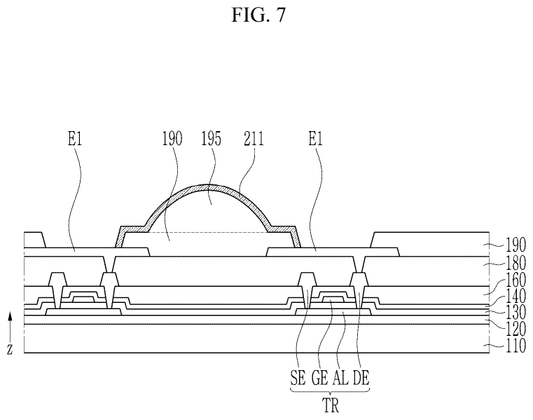

Hereinafter, a method of manufacturing a display device illustrated in FIGS. 2 to 6 will be described with reference to FIGS. 7 to 11.

FIGS. 7 to 11 are schematic cross-sectional views illustrating a method of manufacturing a light emitting display device according to an embodiment.

Referring to FIG. 7, the buffer layer 120 may be formed on the substrate 110. The transistor TR may be formed on the substrate 110. For example, the buffer layer 120 may be formed on the substrate 110, and a semiconductor material layer of the transistor TR may be formed on the buffer layer 120 and then patterned to form the semiconductor layer AL. The first gate insulating layer 130 may be formed on the semiconductor layer AL. A conductive material layer may be formed on the first gate insulating layer 130 and then patterned to form the gate conductive layer that may include the gate electrode GE of the transistor TR. The second gate insulating layer 140 may be formed on the gate conductive layer. The conductive material layer may be formed on the second gate insulating layer 140 and then patterned to form the data conductive layer that may include the first electrode SE of the transistor TR and the second electrode DE of the transistor TR.

The interlayer insulating layer 160 may be formed on the first electrode SE and the second electrode DE. The insulating layer 180 may be formed on the interlayer insulating layer 160. The insulating layer 180 may be provided as a planarized layer. A contact hole overlapping at least one of the first electrode SE and the second electrode DE may be formed on the insulating layer 180 that may be provided as a planarized layer. A light emitting device that may be electrically connected to the transistor TR may be formed on the insulating layer 180.

A conductive material layer may be formed on the insulating layer 180 that may be provided as a planarized layer and then patterned to form the pixel electrode E1 of the light emitting device. The pixel electrode E1 may be electrically connected to the transistor TR through a contact hole formed in the insulating layer 180.

The pixel defining layer 190 may be formed by coating an organic material layer on the insulating layer 180 and then patterning it. The spacer 195 may be formed on the pixel defining layer 190. The pixel defining layer 190 and the spacer 195 may be formed independently or simultaneously. The spacer 195 may be formed to contact a fine metal mask to prevent the pre-formed structure from being damaged by the fine metal mask used during deposition of the light emitting layer. The spacer 195 may have various planar shapes, such as a polygon such as a triangle or a circle.

A protective layer may be formed on the spacer 195. Forming the protective layer may include forming the first layer on the spacer 195 and forming the second layer on the first layer.

The spacer 195 may include the central portion, the step portion surrounding the central portion, and the peripheral portion surrounding the step portion. The central portion may refer to a region from the center of the spacer 195 to a predetermined distance. The step portion may refer to a region from the outer edge of the central portion to a predetermined distance. The peripheral portion may refer to a region from the outer edge of the step portion 197 to the outer edge of the spacer 195.

A preliminary first layer 211 may be formed on the spacer 195. A first metal oxide may be deposited on the spacer 195. The first metal oxide may include substantially the same material as the metal oxide described with reference to FIGS. 4 and 5. The first metal oxide may be entirely deposited on the spacer 195 to form the preliminary first layer 211.

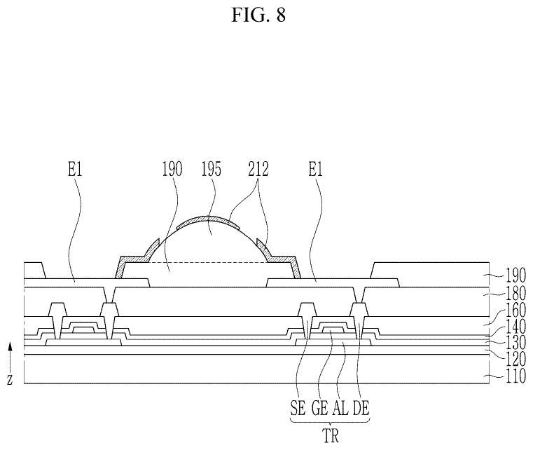

Referring to FIG. 8, a first photoresist may be applied on the spacer 195 on which the preliminary first layer 211 is formed. The first photoresist may be a negative photoresist. The first photoresist may be applied to the central portion and the peripheral portion of the spacer 195 on which the preliminary first layer 211 is formed. Accordingly, the step portion may be etched. The first photoresist may also be applied to a portion above what will become the step portion of the spacer 195 on which the preliminary first layer 211 is formed. Accordingly, the preliminary first layer 211 positioned on a portion above what will become the step portion on which the first photoresist is applied may not be removed.

The spacer 195 on which the first photoresist is applied may be etched. At least a portion of the preliminary first layer 211 positioned above what will become the step portion may be removed by etching. A portion of the preliminary first layer 211 positioned above what will become the step portion may not be etched. The unetched preliminary first layer 211 above what will become the step portion may be provided as a wing of the protective layer. For example, at least a portion of the preliminary first layer 211 may be etched to form a portion of a wing positioned above what will become the step portion.

The etching may be performed by a wet process. For example, the spacer 195 on which the first photoresist is applied may be placed in an etching solution to remove the preliminary first layer 211 formed in the region of the portion where the first photoresist is not applied.

The first photoresist may be removed to form an etched preliminary first layer 212 from which a portion of the preliminary first layer 211 is removed. For example, a portion of the preliminary first layer 211 positioned at the step portion of the spacer 195 may be removed to form the etched preliminary first layer 212.

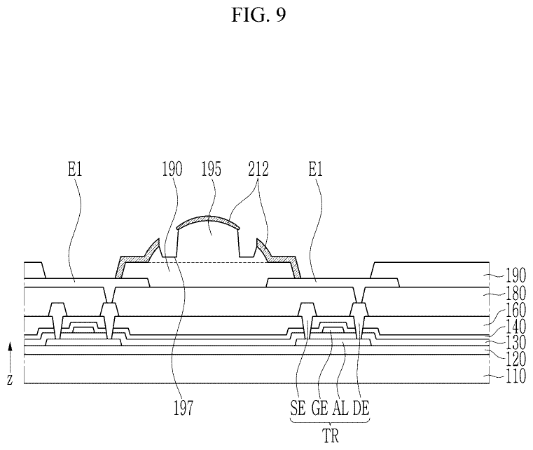

Referring to FIG. 9, an ashing process may be performed to form the step portion 197 of the spacer 195 on which the etched preliminary first layer 212 is formed. Accordingly, the step portion 197 may have a concave hole in the direction of the pixel defining layer 190.

The forming of the step portion 197 may include plasma-treating the surface of the step portion 197. The ashing process may include plasma treatment using plasma. For example, the ashing process may be performed using helium (He) plasma, oxygen (O₂) plasma, nitrogen (N₂) plasma, or the like. Accordingly, the surface of the step portion 197 of the spacer 195 may be modified. Accordingly, outgassing, in which gas is released through the step portion 197, may be suppressed, and stains such as dots may be prevented from occurring due to outgassing through the step portion 197.

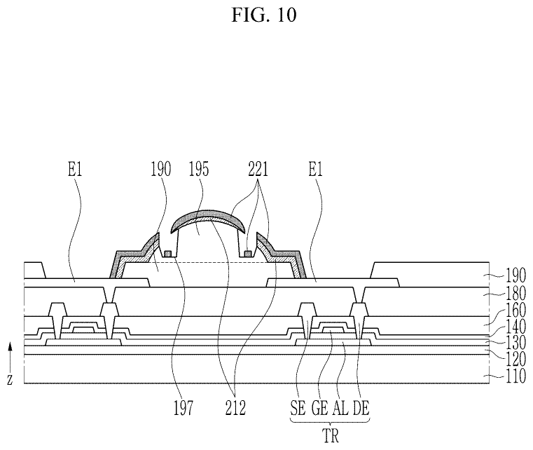

Referring to FIG. 10, a second metal oxide may be additionally deposited on the spacer 195 on which the etched preliminary first layer 212 is formed. Accordingly, a preliminary second layer 221 may be formed. The second metal oxide may include substantially the same material as the metal oxide described with reference to FIGS. 5 and 6.

A second photoresist may be applied on the preliminary second layer 221 and on the etched preliminary first layer 212. The second photoresist may be a negative photoresist. The second photoresist may be applied to the central portion of the spacer 195. The second photoresist may also be applied to a portion of the step portion 197 of the spacer 195. The second photoresist may also be applied to a portion of the step portion 197, so that a protective layer may be formed on the step portion 197 and spaced apart from the step portion 197. The second photoresist may also be partially applied on the preliminary second layer 221 positioned on the step portion 197 and in contact with the step portion 197.

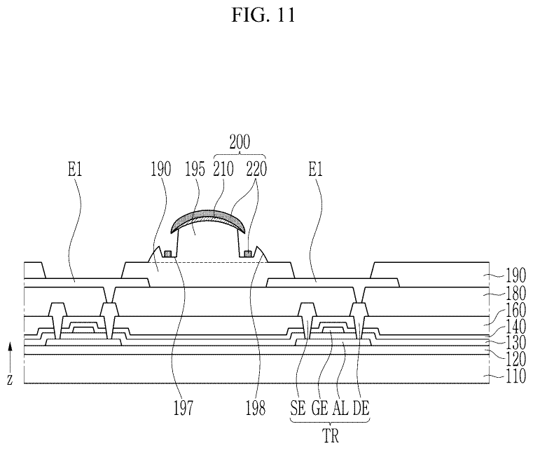

Referring to FIG. 11, the spacer 195 to which the second photoresist is applied may be etched. At least a portion of the preliminary second layer positioned on the step portion 197 may be removed by etching. A portion of the preliminary second layer positioned on the step portion 197 may not be etched. The unetched preliminary second layer may form a wing of the second layer on a wing of the first layer. For example, a wing may be formed by forming the wing of the second layer positioned on the wing of the first layer.

The etching may be performed by a wet process. For example, the spacer 195 on which the second photoresist is applied may be placed in an etching solution to remove the preliminary first layer and the preliminary second layer formed in the region of the portion where the second photoresist is not applied. Accordingly, the etched preliminary first layer and preliminary second layer positioned on the peripheral portion 198 may be removed to form the first layer 210 and the second layer 220.

The preliminary first layer and the preliminary second layer may be etched so that the end of the wing have an internal angle of about 30° to about 50°, about 35° to about 50°, or about 35° to about 45°. Accordingly, the wing may have an appropriate thickness, so defects such as cracks in the wing caused by external forces may be suppressed.

The first layer 210 and the second layer 220 formed by etching the etched preliminary first layer and preliminary second layer may also be cured. Accordingly, the strength of the protective layer 200 including the first layer 210 and the second layer 220 may be improved. Accordingly, even if a mask for forming a light emitting layer is positioned on the protective layer 200, defects such as cracks may not occur in the protective layer 200. For example, the curing may be performed by irradiating ultraviolet rays.

An intermediate layer including a light emitting layer and a functional layer may be formed on the pixel electrode E1. The light emitting layer may be deposited using a fine metal mask. The functional layer may be fully deposited using an open mask. The functional layer may include two or more functional layers.

For example, a first functional layer, a light emitting layer, and a second functional layer may be formed sequentially. The first functional layer and the second functional layer may be fully deposited using an open mask. Accordingly, the first functional layer and the second functional layer may be formed over the entire display area. The light emitting layer may be deposited using a fine metal mask. The light emitting layer may be formed widely considering the margin of the deposition process, and accordingly, a portion of the light emitting layer may also be positioned on the pixel defining layer 190.

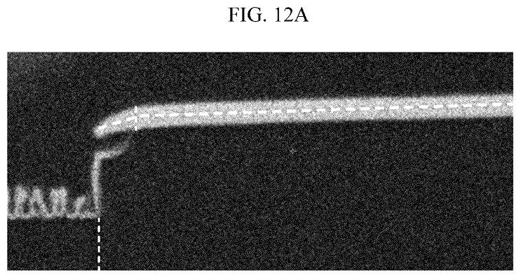

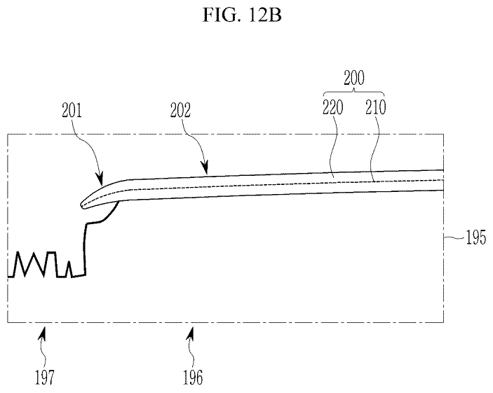

FIG. 12A is a photograph taken by an electron microscope of a portion of a spacer and a portion of a protective layer included in a display device according to an embodiment. FIG. 12A is a photograph of a portion of the spacer and a portion of the protective layer manufactured by the method described above. FIG. 12B is a line drawing of features shown in the photograph of FIG. 12A.

Referring to FIGS. 12A and 12B, the protective layer 200 with two layers, including the first layer 210 and the second layer 220, is formed on the spacer 195. The protective layer 200 includes the body 201 positioned at the central portion 196 of the spacer 195 and the wing 202 positioned at the step portion 197 of the spacer 195. Additionally, the end of the wing 202 includes an inclined surface at a certain angle. Accordingly, it can be seen that the protective layer 200 manufactured according to the above-described manufacturing process includes the body 201 and the wing 202 and is stably formed on the spacer 195.

### EXAMPLES AND COMPARATIVE EXAMPLES

### Example 1

A preliminary first protective unit was formed by depositing IGZO on a spacer including a central portion, a step portion, and a peripheral portion, and a first photoresist was applied to the central portion and a portion of the step portion. The spacer coated with the first photoresist was placed in an etching solution, and a wet etching process was performed to manufacture a spacer on which an etched preliminary first protective unit was deposited.

A preliminary second protective unit was formed by additionally depositing IGZO on the preliminary first protective unit, and a second photoresist was applied to the central portion and a portion of the step portion. The spacer coated with the second photoresist was placed in an etching solution, and a wet etching process was performed to manufacture a spacer having a protective layer including a first protective unit and a second protective unit deposited thereon.

### Examples 2 and 3

A spacer with a protective layer deposited thereon was additionally manufactured using the same method as in Example 1.

### Comparative Example 1

IGZO was deposited on a spacer including a central portion, a step portion, and a peripheral portion, and the first photoresist was applied to the central portion and a portion of the step portion. A spacer coated with a first photosensitive agent was immersed in an etching solution, and a wet etching process was performed to manufacture a spacer with a preliminary protective layer deposited thereon.

The second photoresist was applied to the central portion and a portion of the step portion of the spacer on which the preliminary protective layer was deposited. A spacer coated with the second photoresist was placed in an etching solution and a wet etching process was performed to manufacture a spacer with a protective layer deposited thereon.

### Experimental Results

The angles of the end of the spacer with the protective layer manufactured according to the examples and comparative example deposited thereon were measured. The measured angles are shown in Table 1 below.

TABLE 1

| Category | Angle of end of spacer | Average of angles |
|---|---|---|
| Example 1 | 38.4° | 41.4° |
| Example 2 | 44.3° | |
| Example 3 | 41.4° | |
| Comparative | 20.4° | 20.4° |
| Example 1 | | |

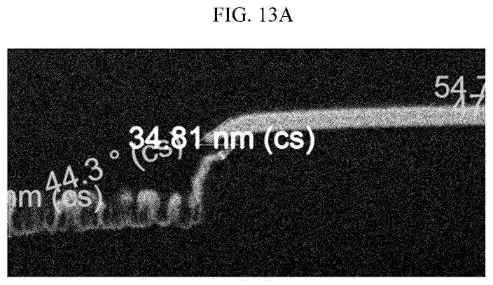

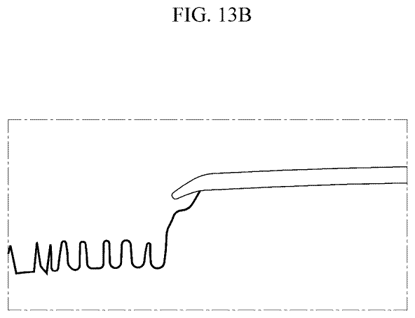

FIG. 13A is a photograph taken by an electron microscope of a portion of a spacer and a portion of a protective layer included in a display device according to an embodiment. FIG. 13A is a photograph taken by an electron microscope of a portion of a spacer having a protective layer formed according to Example 2. FIG. 13B is a line drawing of features shown in the photograph of FIG. 13A. Referring to FIGS. 13A and 13B, and Table 1, when the protective layer was formed as a two-layer structure including the first layer and the second layer, the angle at the end of the spacer was maintained at 40° to 50°. Therefore, the protective layer may have a strong structure, so defects such as cracks may be reduced.

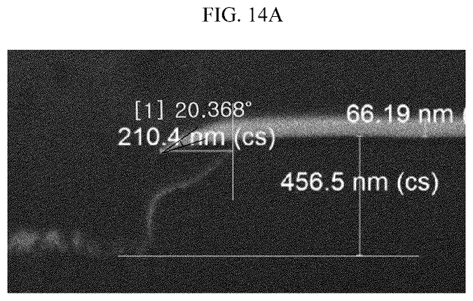

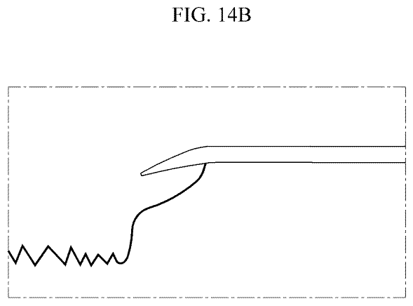

FIG. 14A is a photograph taken by an electron microscope of a portion of a spacer and a portion of a protective layer included in a display device according to a comparative example. FIG. 14A is a photograph taken by an electron microscope of a portion of a spacer having a protective layer formed according to Comparative Example 1. FIG. 14B is a line drawing of features shown in the photograph of FIG. 14A.

Referring to FIGS. 14A and 14B, and Table 1, when the protective layer was formed as a single layer, the angle at the end of the spacer decreased. Therefore, the protective layer may become weaker, which may increase defects such as cracks.

A display device according to an embodiment may be applied to various electronic devices. An electronic device according to an embodiment may include the display device, and may further include modules or devices having additional functions other than the display device.

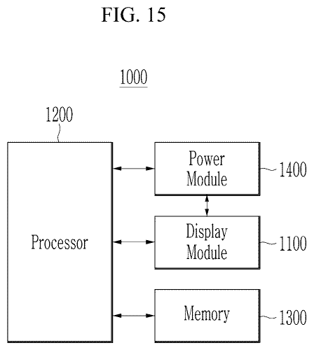

FIG. 15 is a block diagram of an electronic device according to an embodiment. Referring to FIG. 15, the electronic device 1000 according to an embodiment may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller

The memory 1300 may store data information necessary for operations of the processor 1200 or the display module 1100. When the processor 1200 executes an application stored in the memory 1300, video data signals and/or input control signals are transmitted to the display module 1100, and the display module 1100 can process the received signals to output video information through the display screen.

The power module 1400 may include a power supply module such as a power adapter or battery device, and a power conversion module that converts the power supplied by the power supply module to generate the power necessary for the operation of the electronic device 1000.

At least one of components of the electronic device 1100 may be included within the display device according to the above-described embodiments. Additionally, some of the individual modules that are functionally included within a single module may be incorporated into the display device, while others may be provided separately from the display device. For example, the display device may include the display module 1100, while the processor 1200, memory 1300, and power module 1400 may be provided in a form of other devices within the electronic device 1100 that are not part of the display device.

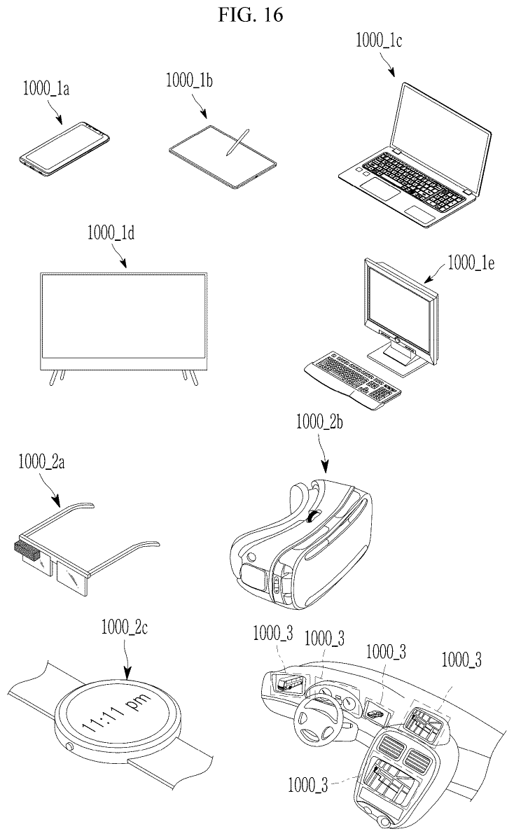

FIG. 16 shows schematic diagrams of electronic devices according to various embodiments

Referring to FIG. 16, various electronic devices with the display device according to the embodiments may include not only image display electronic devices such as smartphones 1000_1a, tablet PCs 1000_1b, laptops 1000_1c, TVs 1000_1d, desktop monitors 1000_1e, but also wearable electronic devices with display modules such as smart glasses 1000_2a, head-mounted displays 1000_2b, smart watches 1000_2c, as well as automotive electronic devices with display modules 1000_3 such as those placed on car dashboards, center fascias, CID (Center Information Display), room mirror displays, and so on.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A light emitting display device, comprising:
a substrate;
a transistor positioned on the substrate;
an insulating layer positioned on the transistor;
a pixel electrode positioned on the insulating layer and electrically connected to the transistor;
a pixel defining layer positioned on the insulating layer and having an opening overlapping the pixel electrode;
a spacer positioned on the pixel defining layer; and
a protective layer positioned on the spacer,
wherein the protective layer comprises a first layer positioned on the spacer and a second layer positioned on the first layer.

2. The light emitting display device of claim 1, wherein
the spacer comprises a central portion including a center of the spacer, a step portion surrounding the central portion, and a peripheral portion surrounding the step portion,
and the step portion has a concave step in a direction of the pixel defining layer.

3. The light emitting display device of claim 2, wherein
the protective layer comprises a body positioned on the central portion and a protective layer wing positioned on the step portion.

4. The light emitting display device of claim 3, wherein
the body contacts the central portion,
and the protective layer wing is spaced apart from the step portion.

5. The light emitting display device of claim 3, wherein
a thickness of the protective layer wing is smaller than a thickness of the body.

6. The light emitting display device of claim 5, wherein
ends of the protective layer wings have an internal angle of 30° to 50°.

7. The light emitting display device of claim 2, wherein
the protective layer is not positioned on the peripheral portion.

8. The light emitting display device of claim 1, wherein
the protective layer comprises a metal oxide.

9. The light emitting display device of claim 1, comprising:
an intermediate layer positioned on at least one of the pixel electrode, the pixel defining layer, the spacer, and the protective layer, and including a light emitting layer and a functional layer; and
a common electrode positioned on the intermediate layer,
wherein the protective layer is positioned between the spacer and the intermediate layer.

10. The light emitting display device of claim 9, comprising:
an encapsulation substrate positioned on the common electrode;
a filler positioned between the common electrode and the encapsulation substrate; and
a sealing member positioned at an edge of the substrate and bonding the substrate and the encapsulation substrate.

11. An electronic device, comprising:
a light emitting display device comprising:
a substrate;
a transistor positioned on the substrate;
an insulating layer positioned on the transistor;
a pixel electrode positioned on the insulating layer and electrically connected to the transistor;
a pixel defining layer positioned on the insulating layer and having an opening overlapping the pixel electrode;
a spacer positioned on the pixel defining layer; and
a protective layer positioned on the spacer,
wherein the protective layer comprises a first layer positioned on the spacer and a second layer positioned on the first layer.

12. A method of manufacturing a light emitting display device, comprising:
forming a transistor on a substrate;
forming an insulating layer on the transistor;
forming a pixel electrode electrically connected to the transistor on the insulating layer;
forming a pixel defining layer having an opening overlapping the pixel electrode on the insulating layer;
forming a spacer on the pixel defining layer; and
forming a protective layer on the spacer,
wherein the forming of the protective layer comprises forming a first layer on the spacer and forming a second layer on the first layer.

13. The method of manufacturing the light emitting display device of claim 12,
wherein the forming of the protective layer comprises forming a preliminary first layer on the spacer;
etching the preliminary first layer to form an etched preliminary first layer;
forming a preliminary second layer on the etched preliminary first layer and the spacer; and
etching together the etched preliminary first layer and the preliminary second layer to form a first layer and a second layer.

14. The method of manufacturing the light emitting display device of claim 13, wherein
the forming of the preliminary first layer comprises depositing a first metal oxide on the spacer,
and the forming of the preliminary second layer comprises depositing a second metal oxide on the etched preliminary first layer and the spacer.

15. The method of manufacturing the light emitting display device of claim 13, further comprising
forming a step portion by ashing a portion of the spacer.

16. The method of manufacturing the light emitting display device of claim 15, wherein
the forming of the step portion comprises plasma-treating a surface of the step portion.

17. The method of manufacturing the light emitting display device of claim 15, wherein
the forming of the step portion is performed by ashing a region where the spacer does not overlap the etched preliminary first layer.

18. The method of manufacturing the light emitting display device of claim 13, wherein
the spacer comprises a central portion including a center of the spacer, a step portion surrounding the central portion, and a peripheral portion surrounding the step portion, and
the forming of the first layer and the second layer comprises etching the etched preliminary first layer and the preliminary second layer formed on the peripheral portion.

19. The method of manufacturing the light emitting display device of claim 18, wherein
the etching of the preliminary first layer comprises forming a first layer wing positioned on the step portion and
the forming of the second layer comprises forming a second layer wing positioned on the first layer wing to form a protective layer wing.

20. The method of manufacturing the light emitting display device of claim 19, wherein
the forming of the protective layer wing comprises etching the preliminary first layer and the preliminary second layer so that the end of the protective layer wing has an inner angle of 30° to 50°.
